(19) United States
(12) Patent Application Publication
(10) Pub. No.: US 2010/0174858 A1
(43) Pub. Date: Jul. 8, 2010

(54) EXTRA HIGH BANDWIDTH MEMORY DIE STACK

(75) Inventors: Ming-Fa CHEN, Taichung City (TW); Chao-Shun Hsu, San-Shin (TW); Clinton Chih-Chieh Chao, Hsinchu (TW); Chen-Shien Chen, Zhubei City (TW)

Correspondence Address: DUANE MORRIS LLP (TSMC);IP DEPARTMENT, 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 12/348,735

(22) Filed: Jan. 5, 2009

(51) Int. Cl. G06F 13/28; G06F 12/00

(52) U.S. Cl. 711/105; 710/22; 711/E12.001

(57) ABSTRACT

A system includes a central processing unit (CPU); a memory device in communication with the CPU, and a direct memory access (DMA) controller in communication with the CPU and the memory device. The memory device includes a plurality of vertically stacked chips and a plurality of input/output (I/O) ports. Each of the I/O ports connected to at least one of the plurality of chips through a through silicon via. The DMA controller is configured to manage to transfer of data to and from the memory device.

### FIELD OF DISCLOSURE

The disclosure relates to memory devices. More specifically, the disclosure relates to memory devices formed using three dimensional die stacks.

### BACKGROUND

Stacking memory chips is conventionally used to increase the capacity of a memory device while reducing its silicon footprint. Two conventional methods of stacking are Package-on-Package (PoP) and System-in-Package (SiP). In a PoP system, discrete logic and memory ball grid array (BGA) are vertically combined in a package. The two packages rest on top of one another and are connected with a standard interface that routes signals between the two packages. In a SiP implementation, a number of dies are vertically stacked and are connected using conventional off-chip wire bonds or solder bumps.

Recently 3D integrated circuits (ICs) that utilize through silicon vias (TSVs) for interconnection have been developed as an improved alternative to the PoP and SiP packages. TSV technology utilizes vertical vias in the silicon (or other dielectric material) wafers that are used to interconnect each of the chips. Using through silicon vias results in shortened interconnect length, improved electrical performance, and reduced power consumption by the memory device.

TSV technology has been incorporated into memory storage devices that conform to conventional standards such as DDR2 and DDR3 SDRAM. To create a 1 gigabit DRAM, eight 128 Mb chips may be stacked on top of one another and are connected using through silicon vias. Although stacked vertically, a 3D IC memory device reads and writes data in accordance with the conventional memory standards, e.g., DDR2 and DDR3. For example a DDR2 SDRAM circuit has a prefetch buffer that is 4 bits deep and accesses data storage locations using a multiplexer. For DDR2 SDRAM, DDR2 memory cells transfer data both on the rising and falling edge of the system clock to enable four bits of data to be transferred per memory cell cycle. DDR3 SDRAM has a higher bandwidth than DDR2 and has the ability to transfer data at eight times the speed of the memory cells using an 8-bit prefetch buffer.

Although TSV technology has been used to increase the data storage capacity of a memory device, the speed at which the device may be read from and written to is constrained by the specification to which they conform, e.g., DDR2 and DDR3, and the bandwidth of the devices remains unchanged.

### SUMMARY

In one embodiment, a system comprises a central processing unit (CPU), a memory device in communication with the CPU, and a direct memory access (DMA) controller in communication with the CPU and the memory device. The memory device includes a plurality of vertically stacked chips and a plurality of input/output (I/O) ports. Each of the I/O ports is connected to at least one of the plurality of chips through a through substrate via. The DMA controller is configured to manage to transfer of data to and from the memory device.

In one embodiment, a memory system includes a storage device and a controller connected to the storage device. The storage device comprises first and second integrated circuit chips. Each of the first and second integrated circuit chips comprises a plurality of memory locations and through silicon vias. Each of the through silicon vias corresponds to a respective input/output (I/O) port. The controller is configured to manage writing data to and reading data from each of the memory locations of the first and second integrated circuit chips.

### BRIEF DESCRIPTION OF THE DRAWINGS

FIG. 1 is a block diagram of an electrical system in accordance with the present disclosure.

FIG. 2A is a block diagram of the architecture of the memory device in accordance with the electrical system shown in FIG. 1.

FIG. 2B is a cross-sectional view of the memory device illustrated in FIG. 2A.

FIG. 3 is a block diagram of the DMA controller in accordance with the electrical system shown in FIG. 1.

### DETAILED DESCRIPTION

As used herein, the terms “through-silicon via” (TSV) and “though-substrate via are used interchangeably to refer to a configuration including a through-via penetrating an integrated circuit (IC) semiconductor substrate, and are not limited to ICs formed on substrates of silicon material. Thus, the term TSV as used herein can also encompass a through-substrate via that is formed through a different semiconductor IC substrate material, such as a III-V compound substrate, a silicon/germanium (SiGe) substrate, a gallium arsenide (GaAs) substrate, a silicon-on-insulator (SOI) substrate, or the like.

A novel approach for high bandwidth memory die stacking is now disclosed. In the following detailed description, reference is made to the accompanying drawings which form a part of the detailed description.

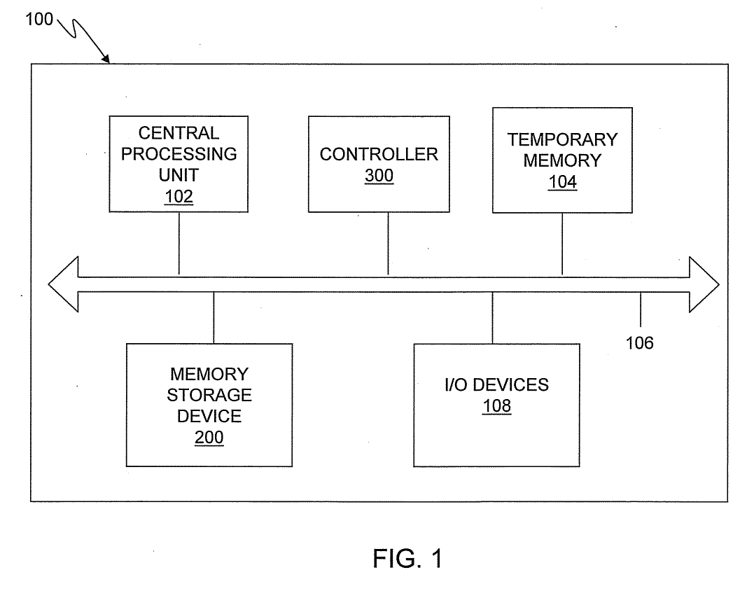

FIG. 1 is a simplified block diagram of one example of an electronic system 100 in accordance with the present disclosure. In some embodiments, the system 100 is configured as a system in a package. In other embodiments, the system 100 is configured on a printed circuit board. Electronic system 100 may be included in a computer, personal digital assistant (PDA), cellular phone, DVD player, set top box or other electronic device. Electronic system 100 includes a central processing unit (“CPU”) 102, a read only memory (“ROM”) 104, a system bus 106, I/O devices 108, a main memory 200, and a direct memory access (“DMA”) controller 300.

CPU 102 may be any processor that may performs computing functions. Examples of such processors include, but are not limited to, “INTEL® CORE”™, “PENTIUM”®, “CELERON”®, or “XEON”® processors available from Intel of Santa Clara, Calif., as well as an AMD “PHENOM”™, “ATHLON”™, or “SEMPRON”™ processors from AMD of Sunnyvale, Calif. The CPU 102 is connected to ROM 104, main memory 200, I/O devices 108, and DMA controller 300 through system bus 106.

System bus 106 may include a data bus used to transfer data from one of the memory devices 104, 200 to the CPU 102 or to an I/O device, an address bus used to transfer the source and destination address of the data, and a control bus used to transmit signals controlling how the data are being transmitted. System bus 106 may also include a power bus and I/O bus. The busses that comprise the system bus 106 are not shown to simplify the figures. In one embodiment, the width of system bus 106 may be 64-bits; however, other bus widths may be used.

ROM 104 may be any read only memory including, but not limited to, programmable read only memory (“PROM”), erasable programmable read only memory (“EPROM”), electrically erasable programmable read only memory (“EEPROM”), and flash memory.

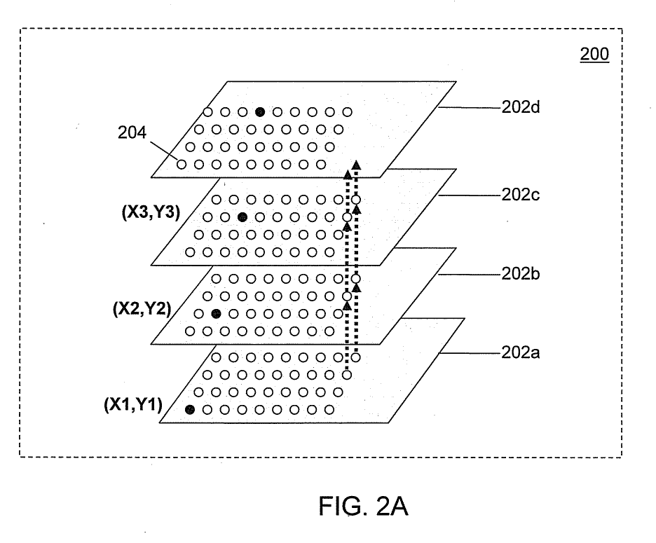

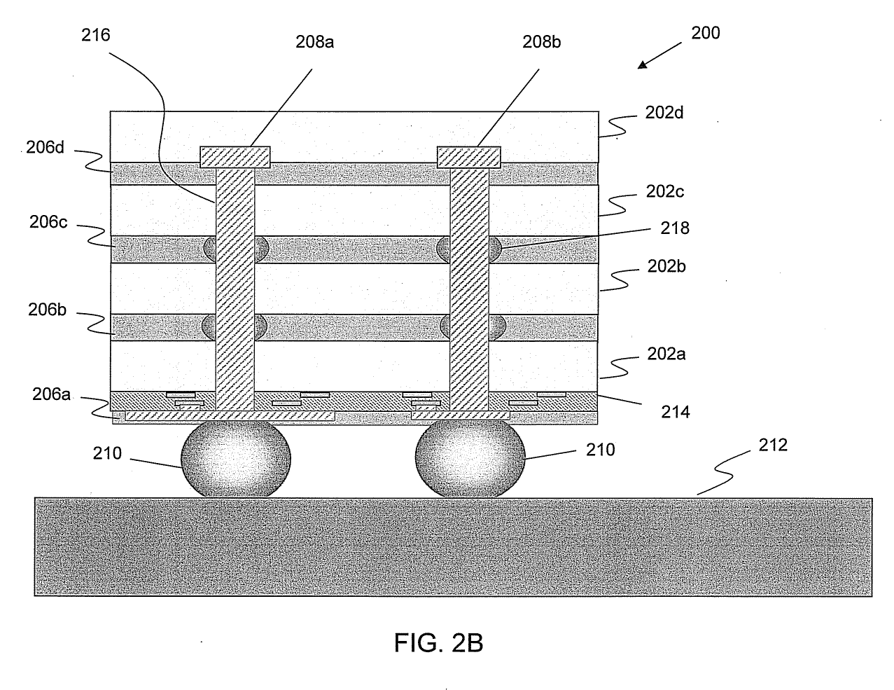

FIG. 2A and 2B illustrate an exemplary architecture of a memory storage device 200, which is contained within a single 3D-IC package. Memory storage device 200 is shown as a vertical stack of four integrated circuit (“IC”) chips 202a-202d. Note that although four chips are described, memory storage device 200 may be configured with fewer or more chips depending on the amount of memory desired for a system. Each chip 202 may have a memory capacity of 128 MB, although chips with more or less memory capacity may be implemented. Each chip 202 includes a plurality of storage locations 204, with each storage location on each memory chip 202 having a unique memory address. In some embodiments, storage device 200 may be a dynamic random access memory (DRAM) storage device, although other memory types including, but not limited to, static random access memory (“SRAM”) and read only memory may be used.

Memory chips 202 are connected to one another using through-silicon via (“TSV”) technology. For example, each of the chips 202 may be connected to each other using laser-cut holes which are filled with a conductive metal as shown in FIG. 2B. One example of stacking a plurality of chips is disclosed in U.S. Pat. No. 7,317,256 entitled “Electronic Packaging Including Die with Through Silicon Via” issued on Jan. 8, 2008, which is incorporated by reference herein in its entirety.

As shown in FIG. 2B, memory device 200 includes IC memory chips 202a-202d formed over a semiconductor substrate 212. Semiconductor substrate may be formed from any semiconductor material including, but not limited to, silicon, gallium arsenide (GaAs), a group Ill-V compound, silicon/germanium (SiGe), silicon-on-insulator (SOI), or the like.

The stack of IC memory chips 202a-202d are connected to the semiconductor substrate 212 by one or more solder bumps 210. Solder bumps 210 may be formed from lead or lead-free alloys. Examples of lead-free alloys include, but are not limited to, tin/silver, tin/copper/silver, copper, copper alloys, and the like.

The stacked IC memory chips 202a-202d may be separated from adjacent chips by spacers 206a-206d. For example, as shown in FIG. 2B, IC memory chips 202b and 202c are separated by spacer 206c. Spacers 206a-206d may be formed from a variety of materials including, but not limited to, silicon, gallium arsenide, and the like. Each of the memory chips 202a-202d may be connected by a joint 218, which is also connected to the spacers 206a-206d. In some embodiments, memory device 200 may include a layer of an extremely low k (ELK) material 214 formed between the first IC memory chip 202a and spacer 206a. Examples of ELK materials include, but are not limited to, carbon doped silicon dioxide, nanoglass, and the like. In some embodiments, an ELK material 214 is replaced by a gap of air.

A through-substrate via 216 is formed through each of the IC memory chips 202a-202d and spacers 206a-206d. The spacers are filled with a conductive material such as copper to form interconnects 208. Vertically stacking and connecting the chips using TSV technology improves the electrical performance and power consumption of the chips by reducing the length of the leads. Additionally, vertical stacking of the chips and interconnecting them using through-substrate vias enables the number of input/output (“I/O”) ports to be increased. The number of I/O ports may be increased because instead of using wire bonding that requires horizontal spacing on the package boards that is hundreds of microns wide to connect the chips, the chips may be connected using laser-cut holes on the order of one micron in width. Thus, connecting the chips using TSV eliminates the need for gaps of extra space for connecting the chips. Increasing the number of I/O ports on a chip increases enables the bandwidth of the chip to be increased as more I/O ports may be used. In some embodiments, each of the through-substrate vias 216 corresponds to an I/O port of the memory device 200.

Data are stored in the memory locations 206 on each of the memory chips 202. The data in memory chips 202 may be read from or written to the memory locations 206 using direct memory access (“DMA”) controlled by controller 300. Utilizing DMA enables the data to be accessed independently of the system clock enabling higher data transfer rates than may be accomplished in conventional DDR2 or DDR3 systems. Additionally, using DMA to access data stored in the memory 200 enlarges the bandwidth through which the data may be accessed as larger amounts of data may be transferred than through conventional memory systems, e.g., DDR2, DDR3, etc.

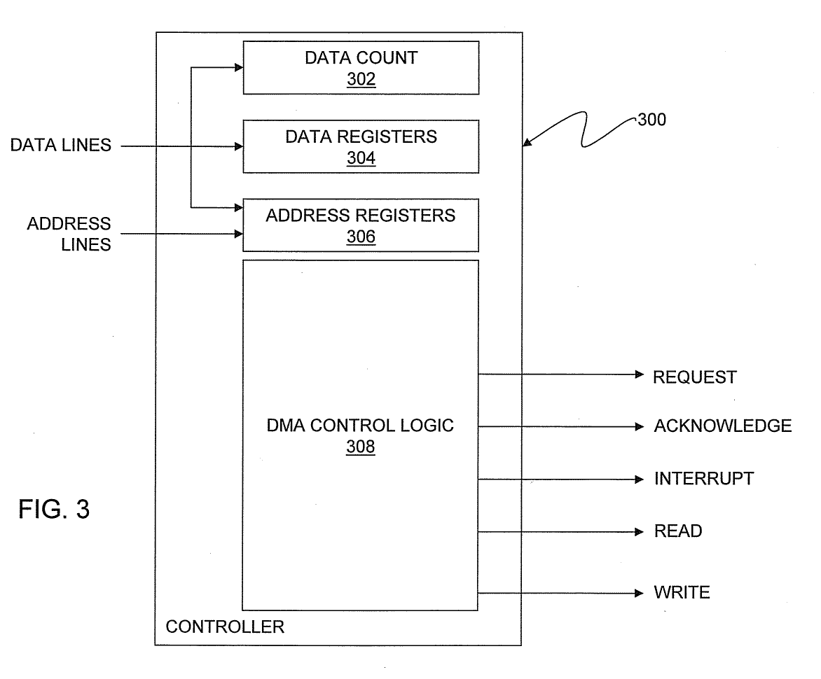

FIG. 3 illustrates one example of a controller 300 in accordance with the disclosure. In some embodiments, controller 300 is included within the same package as the memory storage device 200. Controller 300 may include a data counter 302, a data register 304, an address register 306, and control logic 308. Data counter 302 is used for storing the amount of data that is to be transferred in a particular transaction. As the data is transferred, the data counter 302 is decremented until all of the data has been transferred. Data register 304 is used to save the data being transferred, and the address register 306 is used to save the address of the data being transferred. The data counter 302, data register 304, and address register 306 send and receive signals and data over system bus 106. Control logic 308 communicates with CPU 102 and controls the transfer of data to and from main memory 200.

In some embodiments, controller 300 may receive a request signal from another device or from the CPU 102 to perform a data transfer. Upon receipt of the signal, controller 300 acquires control of the system bus 106 and performs a data transfer. The controller 300 manages the data transfer which may occur in only a few bus read/write cycles. Since the DMA controller 300 is managing-the transfer, the CPU 102 is available to perform other functions during the data transfer. In other embodiments, the controller 300 may be accessed by the CPU 102, which programs the data registers 304 and address registers 306 of controller 300 to perform a data transfer.

The data stored in memory 200 may be transferred in one of several ways during a DMA data transfer. For example, data stored in memory 200 may be transferred in a single bus operation where the data is simultaneously read from the source and written to the destination. This transfer is typically performed by the controller taking control of the system bus 106 from CPU 102 and signaling for the data to be latched onto or off of the system bus 106.

Another way in which data may be transferred is a fetch-and-deposit transfer where the controller 300 fetches or reads the data from one memory address and deposits or writes the data to another address. The fetch-and-deposit manner of transferring data requires two memory cycles, a first cycle to read the data and a second cycle to write the data.

Using DMA to access the data stored in the vertically stacked chips 202 of memory 200 enables the bandwidth of the memory to be increased as the full width of the bus may be used to transfer data. For example, if a bus has a width of 64-bits, then 64-bits of data may be transferred using DMA, which is eight times the amount of data that may be transferred using DDR3, which has an 8-bit prefetch buffer. Additionally, data transferred using DMA does not require the CPU to allocate resources and is transferred using a DMA clock (not shown) independent of the system clock, so the data are transferred faster than data transferred in accordance with conventional memory specification, e.g., DDR2 and DDR3. By connecting the memory chips 202 with through silicon vias, the number of I/O ports of a memory device 200 may be increased which enables a wider bus to be used which also enables the bandwidth of the memory device to be increased.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A system, comprising:
a central processing unit (CPU);
a memory device in communication with the CPU, the memory device comprising a plurality of vertically stacked integrated circuit chips and a plurality of input/output (I/O) ports, each of the I/O ports connected to at least one of the plurality of chips by a through-substrate via; and
a direct memory access (DMA) controller in communication with the CPU and the memory device, the DMA controller configured to manage transfer of data to and from the memory device.

2. The system of claim 1, wherein the memory device is a dynamic random access memory device (DRAM).

3. The system of claim 1, wherein the memory device is a static random access memory device (SRAM).

4. The system of claim 1, wherein the CPU is connected to the memory device through a system bus.

5. The system of claim 4, wherein the DMA controller is connected to the memory device and CPU through the system bus.

6. The system of claim 1, wherein the DMA controller is configured to manage a fetch and deposit data transfer.

7. A memory system comprising:
a storage device comprising first and second integrated circuit chips, each of the first and second integrated circuit chips comprising a plurality of memory locations and through-substrate vias (TSVs), each of the TSVs corresponding to an input/output (I/O) port; and
a controller connected to the I/O ports of the first and second integrated circuit chips, the controller configured to manage writing data to and reading data from each of the memory locations of the first and second integrated circuit chips.

8. The memory system of claim 7, wherein the controller is a direct memory access (DMA) controller.

9. The memory system of claim 7, further comprising a central processing unit (CPU) connected to the storage device and the controller.

10. The memory system of claim 7, wherein the controller is connected to the storage device through a memory bus.

11. The memory system of claim 7, wherein the first and second integrated circuit chips are dynamic random access memory (DRAM) chips.

12. The memory system of claim 7, wherein the first and second integrated circuit chips are static random access memory (SRAM) chips.

13. The memory system of claim 7, wherein the storage device further includes a third integrated circuit chip, the third integrated circuit chips including a plurality of memory locations.

14. The memory system of claim 7, wherein the first and second integrated circuit chips of the storage device are vertically stacked on top of each other.

15. The memory system of claim 7, wherein the controller is a direct memory access controller configured to manage a fetch and deposit data transfer.

16. A method, comprising:
managing transfer of data to and from a memory device using direct memory access (DMA), the managing being performed by a DMA controller, the memory device comprising a plurality of vertically stacked integrated circuit chips and a plurality of input/output (I/O) ports, each of the I/O ports connected to at least one of the plurality of chips by a through-substrate via.

17. The method of claim 16, wherein the controller is connected to the memory device by a memory bus.

18. The method of claim 16, wherein the plurality of vertically stacked integrated circuit chips are dynamic random access memory (DRAM) chips.

19. The method of claim 16, wherein the plurality of vertically stacked integrated circuit chips are static random access memory (SRAM) chips.

20. The method of claim 16, wherein the DMA controller manages a fetch and deposit data transfer.
